(19) United States
(12) Patent Application Publication
(10) Pub. No.: US 2022/0415728 A1
(43) Pub. Date: Dec. 29, 2022

(54) APPARATUS AND METHOD FOR PROBING MULTIPLE TEST CIRCUITS IN WAFER SCRIBE LINES

(71) Applicant: IC ANALYTICA, LLC, Austin, TX (US)

(72) Inventors: Patrick G. DRENNAN, Gilbert, AZ (US); Joseph S. SPECTOR, Austin, TX (US); Richard WUNDERLICH, Austin, TX (US)

(21) Appl. No.: 17/848,991

(22) Filed: Jun. 24, 2022

Related U.S. Application Data
(60) Provisional application No. 63/215,067, filed on Jun. 25, 2021.

(51) Int. Cl. H01L 21/66; G01R 31/28

(52) U.S. Cl. CPC H01L 22/34; G01R 31/2884

(57) ABSTRACT

An apparatus has a semiconductor wafer hosting rows and columns of chips, where the rows and columns of chips are separated by scribe lines. There are test circuit sites in the scribe lines, each test circuit site including contact pads for simultaneous connection to probe card needles, sensor circuit select and control circuitry, and a sensor circuit bank.

### CROSS-REFERENCE TO RELATED INVENTION

This application claims priority to U.S. Provisional Patent Application Ser. No. 63/215,067, filed Jun. 25, 2021, the contents of which are incorporated herein by reference.

### FIELD OF THE INVENTION

This invention relates generally to testing semiconductor wafers. More particularly, this invention relates to techniques for probing multiple test circuits in wafer scribe lines.

### BACKGROUND OF THE INVENTION

FIG. 1 illustrates a known semiconductor wafer testing system including test equipment 100 connected to a probe card 102, which makes connections with pads on a wafer 104. FIG. 2 illustrates a semiconductor wafer 104 with individual chips 200. The individual chips 200 form rows and columns of chips which are separated by scribe lines 202. Within scribe line 202 there are test circuits 204. The test circuits 204 are used during wafer level testing. When testing is completed, a saw is used in the scribe lines to divide the individual chips for subsequent packaging. This cutting process destroys the test circuits 204 in the scribe lines. FIG. 3 illustrates a simple test circuit with a gate pad 300, a source pad 302 and a drain pad 304. A probe card needle 306 is connected to the drain pad 304. FIG. 4 illustrates multiple probe card needles 306 connected to multiple pads 400 of a semiconductor. Repositioning of probe card needles 306 to different sites on a wafer is time consuming.

Thus, there is a need for improved probing of multiple test circuits in wafer scribe lines.

### SUMMARY OF THE INVENTION

An apparatus has a semiconductor wafer hosting rows and columns of chips, where the rows and columns of chips are separated by scribe lines. There are test circuit sites in the scribe lines, each test circuit site including contact pads for simultaneous connection to probe card needles, sensor circuit select and control circuitry, and a sensor circuit bank.

### BRIEF DESCRIPTION OF THE FIGURES

The invention is more fully appreciated in connection with the following detailed description taken in conjunction with the accompanying drawings, in which:

FIG. 1 illustrates a semiconductor wafer testing system known in the prior art.

FIG. 2 illustrates a prior art semiconductor wafer with a scribe line hosting test circuits.

FIG. 3 illustrates a prior art test circuit and associated probe card needle.

FIG. 4 illustrates prior art probe card needles connected to test circuit pads.

FIG. 5 illustrates components associated with embodiments of the invention.

FIG. 6 illustrates probe card needles engaging test circuit pads on different test sites of a wafer with voltage regulators.

FIG. 7 illustrates probe card needles engaging test circuit pads on different test sites of a wafer with switching circuitry.

FIG. 8 illustrates probe card needles engaging test circuit pads on different test sites of a wafer with direct data scan out.

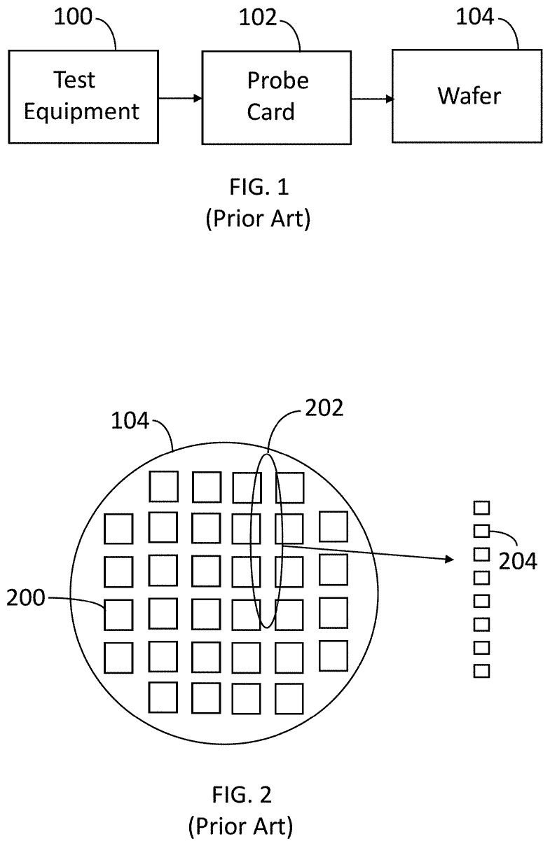

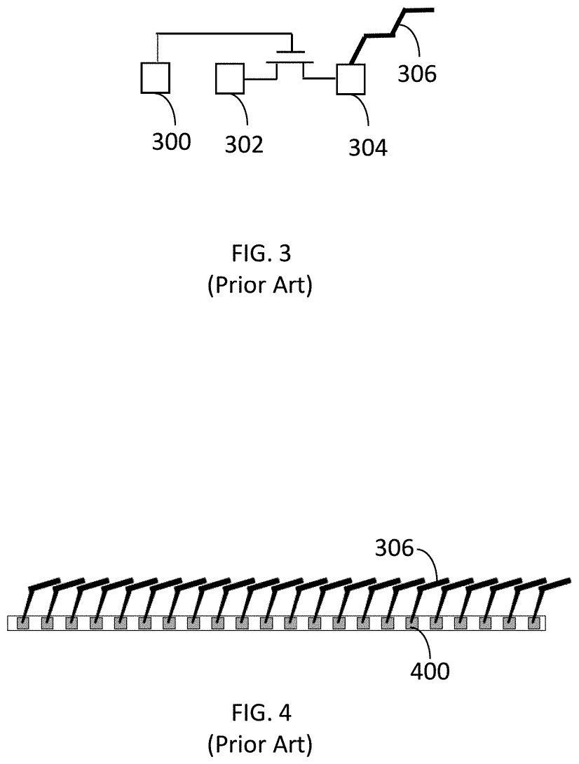

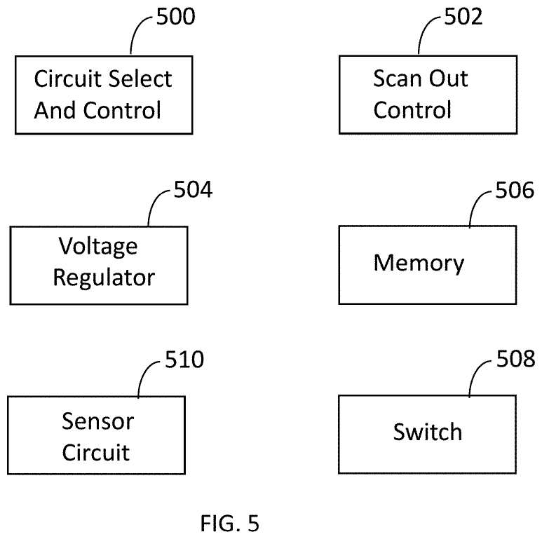

Like reference numerals refer to corresponding parts throughout the several views of the drawings.

### DETAILED DESCRIPTION OF THE INVENTION

FIG. 5 illustrates components of the invention formed in scribe lines of a wafer. The components include circuit select and control circuitry 500, scan out control circuitry 502, one or more voltage regulators 504, one or more memory banks 506, one or more switches 508 and a sensor circuit 510.

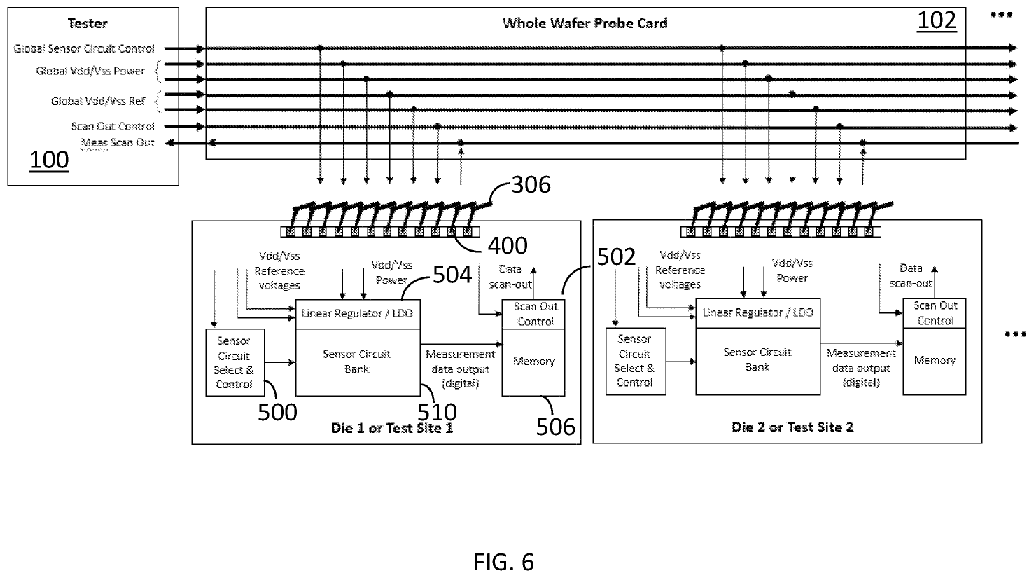

FIG. 6 illustrates a tester 100 connected to a probe card 102, which has probe card needles 306 that are attached to multiple test sites on the wafer. Each test site has the same configuration. Test site 1 in FIG. 6 includes sensor circuit select and control circuitry 500 responsive to the global sensor circuit control from the tester 100. A voltage regulator or linear regulator 504 receives Vdd/Vss power signals and Vdd/Vss reference voltages from the tester 100. The voltage regulator 504 provides a constant voltage output to accommodate process variations and different resistive networks at different test sites. The voltage regulator 504 adjusts the global power Vdd/Vss power signals to match the Vdd/Vss reference voltages.

A sensor circuit bank 510 include test circuitry for wafer testing. The digital data output from the sensor circuit bank 510 is stored in memory 506. The digital data output is subsequently scanned out through scan out control circuit 502, which is responsive to a scan out control signal from tester 100. The digital data output is returned to the tester 100 via the measurement scan out line.

In this embodiment, the global power Vdd/Vss, global Vdd/Vss reference and the global sensor circuit control are applied to all probed die or test sites. There is no dedicated addressing of these terminals. The scan out control circuitry 502 is addressed at each test site.

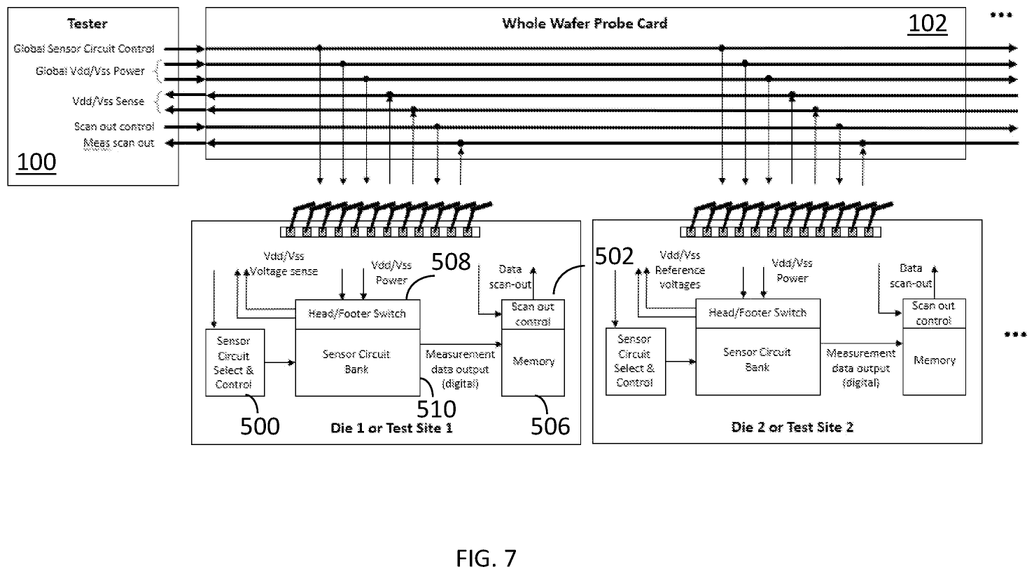

FIG. 7 illustrates an embodiment of the invention where the linear regulator 504 is replaced with a header switch 508. The global Vdd/Vss reference voltages of FIG. 6 are substituted with Vdd/Vss voltage sense signals. In this implementation, the sensor circuit and control 500 is modified to allow for addressing of each test site so that only one test circuit in one sensor circuit bank 510 is running at a time. The Vdd/Vss sense connections connect to the local Vdd and Vss for the selected test circuit. The Vdd/Vss sense voltage can be used to feedback to the global Vdd/Vss power to adjust the global Vdd/Vss power settings so that the intended Vdd and/or Vss sense voltage is obtained at the test circuit. Optionally, Vdd and/or Vss sense voltage does not feedback to the global Vdd/Vss power control but is instead simply measured and recorded in memory 506.

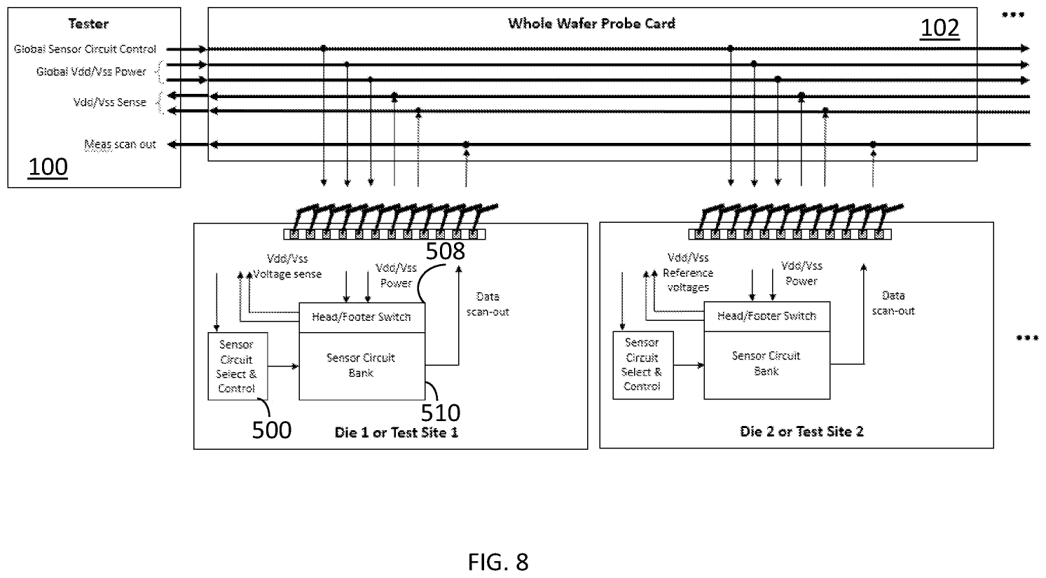

FIG. 8 illustrates an embodiment of the invention without memory 506 or scan out control circuitry 502. Only one test circuit is operative at a time. The digital measurement from the test circuit is immediately scanned out without any special handling for the scan out control.

The foregoing description, for purposes of explanation, used specific nomenclature to provide a thorough understanding of the invention. However, it will be apparent to one skilled in the art that specific details are not required in order to practice the invention. Thus, the foregoing descriptions of specific embodiments of the invention are presented for purposes of illustration and description. They are not intended to be exhaustive or to limit the invention to the precise forms disclosed; obviously, many modifications and variations are possible in view of the above teachings. The embodiments were chosen and described in order to best explain the principles of the invention and its practical applications, they thereby enable others skilled in the art to best utilize the invention and various embodiments with various modifications as are suited to the particular use contemplated. It is intended that the following claims and their equivalents define the scope of the invention.

1. An apparatus, comprising:
a semiconductor wafer hosting rows and columns of chips, where the rows and columns of chips are separated by scribe lines; and
a plurality of test circuit sites in the scribe lines, each test circuit site including
a plurality of contact pads for simultaneous connection to probe card needles, sensor circuit select and control circuitry, and
a sensor circuit bank.

2. The apparatus of claim 1 wherein each test circuit site further includes a voltage regulator.

3. The apparatus of claim 1 wherein each test circuit site further includes a memory with scan out control circuitry.

4. The apparatus of claim 1 wherein each test circuit site further includes a header switch.

5. The apparatus of claim 1 wherein the contact pads include contact pads for Vdd and Vss global power signals.

6. The apparatus of claim 1 wherein the contact pads include contact pads for Vdd and Vss reference signals.

7. The apparatus of claim 1 wherein the contact pads include contact pads for Vdd and Vss sense signals.

8. The apparatus of claim 1 wherein the contact pads include a contact pad for global sensor circuit control signals.

9. The apparatus of claim 1 wherein the contact pads include a contact pad for scan out control signals.

10. The apparatus of claim 1 wherein the contact pads include a contact pad for measurement scan out signals.
